(19) United States
(12) Patent Application Publication
(10) Pub. No.: US 2007/0294047 A1
(43) Pub. Date: Dec. 20, 2007

(54) Calibration system

(76) Inventor: Leonard Hayden, Beaverton, OR (US)

Correspondence Address: CHERNOFF, VILHAUER, MCCLUNG & STENZEL, 1600 ODS TOWER, 601 SW SECOND AVENUE, PORTLAND, OR, 97204-3157, US

(21) Appl. No.: 11/449,979

(22) Filed: Jun. 9, 2006

Related U.S. Application Data
(60) Provisional application No. 60/690,460, filed on Jun. 13, 2005.
(60) Provisional application No. 60/689,597, filed on Jun. 11, 2005.

(51) Int. Cl. G01R 19/00

(52) U.S. Cl. 702/104

(57) ABSTRACT

A calibration system for a probe measurement system including a set up wizard.

### CROSS-REFERENCE TO RELATED APPLICATIONS

This application claims the benefit of U.S. Provisional Application No. 60/690,460, filed Jun. 13, 2005 and U.S. Provisional Application No. 60/689,597, filed Jun. 11, 2005.

### BACKGROUND OF THE INVENTION

The present invention relates to a system for calibrating a probe measurement system.

### BRIEF DESCRIPTION OF THE DRAWINGS

FIG. 1 illustrates a user interface.

FIG. 2 illustrates a user interface.

FIG. 3 illustrates a user interface.

FIG. 4 illustrates a user interface.

FIG. 5 illustrates a user interface.

FIG. 6 illustrates a user interface.

FIG. 7 illustrates a user interface.

FIG. 8 illustrates a user interface.

FIG. 9 illustrates a user interface.

FIG. 10 illustrates a user interface.

FIG. 11 illustrates a user interface.

FIG. 12 illustrates a user interface.

FIG. 13 illustrates a user interface.

FIG. 14 illustrates a user interface.

FIG. 15 illustrates a user interface.

FIG. 16 illustrates a user interface.

FIG. 17 illustrates a user interface.

FIG. 18 illustrates a user interface.

FIG. 19 illustrates a user interface.

FIG. 20 illustrates a user interface.

FIG. 21 illustrates a user interface.

FIG. 22 illustrates a user interface.

FIG. 23 illustrates a user interface.

FIG. 24 illustrates a user interface.

FIG. 25 illustrates a user interface.

FIG. 26 illustrates a user interface.

FIG. 27 illustrates a user interface.

FIG. 28 illustrates a user interface.

FIG. 29 illustrates a user interface.

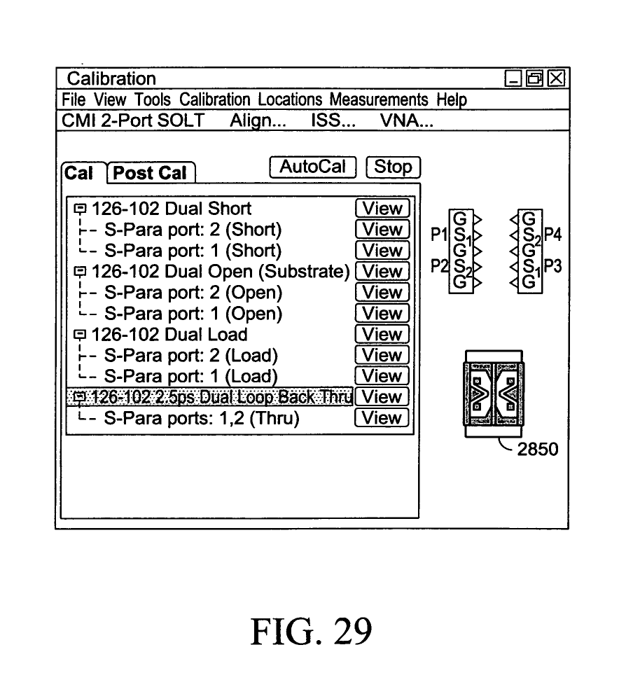

### DETAILED DESCRIPTION OF THE PREFERRED EMBODIMENT

Historically, the set up and configuration of a probe station has been undertaken by highly trained and experienced engineers and scientists who understand the subtleties of the particular configuration being calibrated and the implications of each aspect of the calibration process. In contrast, the set up and calibration of a probe station is a highly problematic task frequently fraught with possible pitfalls when undertaken by technicians and inexperienced engineers. Since there are many different subtleties that should be considered during the calibration of such a probe station there is a reasonable high likelihood that the user calibrating the devices will tend to perform a calibration out of sequence or otherwise forget to perform or check a necessary aspect of the calibration process. The resulting data set of calibration parameters may appear, to the novice operator, as being accurate but will in fact be seriously flawed. Accordingly, it has been determined that an electronic guide, generally known as a wizard, would be of assistance to the technicians and inexperienced engineers to assist them with calibration of the probe station.

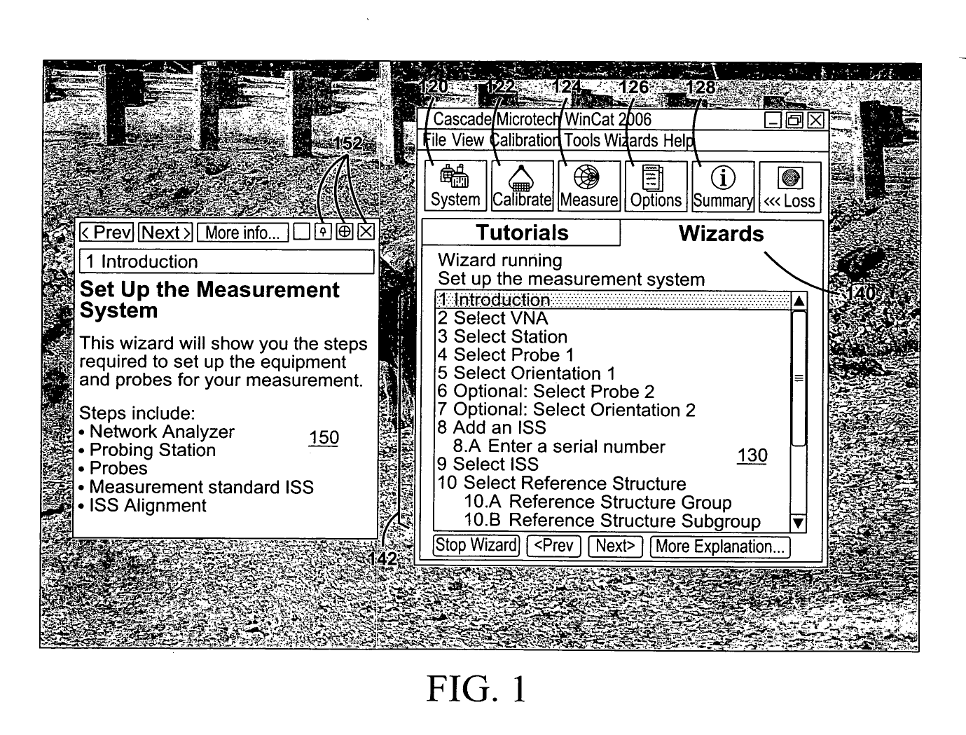

Referring to FIG. 1, the wizard includes a first window 100 which displays a selection of the principal tasks 110 for performing an accurate calibration process. The principal tasks 110 include system 120, calibrate 122, measure 124, options 126, and summary 128. A window 130 indicates that the wizard 140 is being used and the steps 142 that the user is guided through by the wizard 140. The wizard 140 provides an assistance window 150 that includes further information regarding the particular step that is being performed by the user. The description in the assistance window 150 corresponds to the particular item being highlighted by the wizard 140.

The assistance window 150 preferably includes textual information that further guides the user through the calibration process. The assistance window 150 preferably includes an indication 160 to the window 130 or other widow indicating which step in the process it is related to. In this manner, the assistance window 150 follows the user's actions through the calibration process. In most cases, the assistance window 150 does not actually perform or make any of the changes to the settings or initiate any of the calibration actions. This permits the user to actually set all of the settings and initiate any of the calibration actions in order to properly calibrate the system. This avoids potential problems associated with a wizard actually making some or all of the settings on behalf of the user, which is generally undesirable for calibration given the sensitive nature and possible other issues regarding setup that are not accounted for in the wizard. The assistance window 150 includes a function 152 that permits the window to be positioned in a user selected position on the screen or otherwise be automatically repositioned in an open area of the screen as other screens are moved, open, or otherwise the assistance window 150 requires space to present its information.

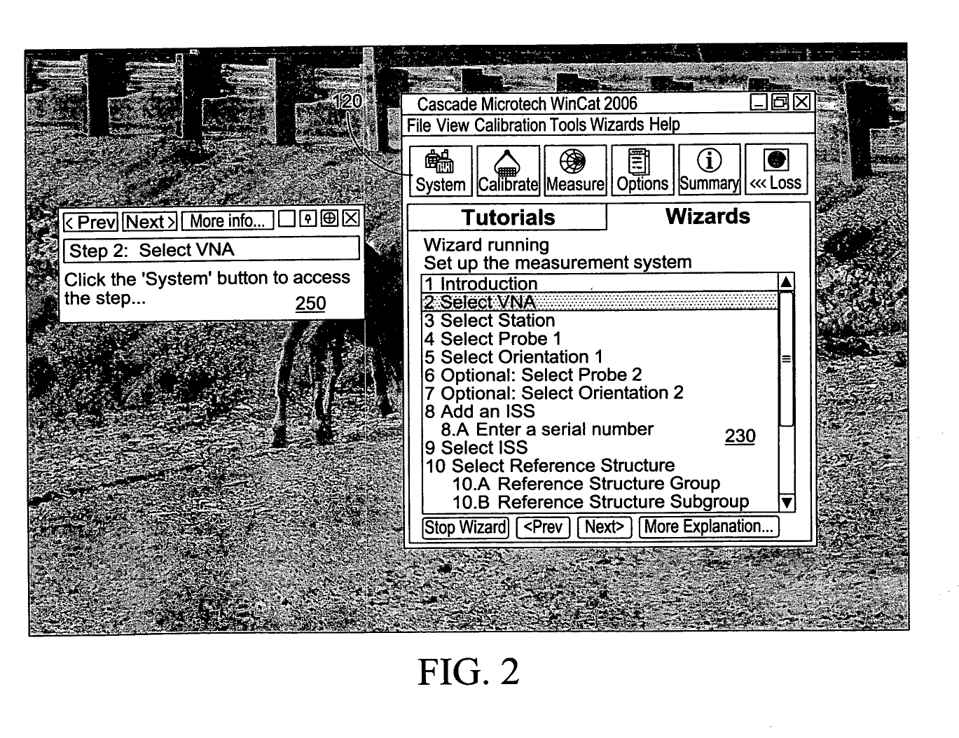

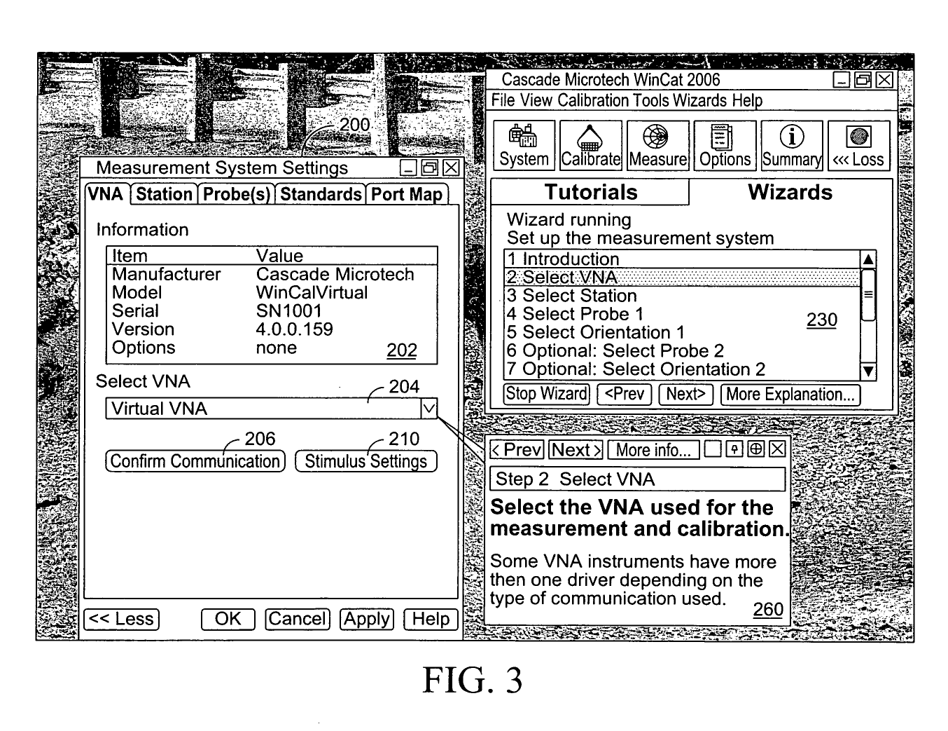

To set up the measurement system, as indicated by the assistance window 150, the user may select the ‘system’ button 120, move to step 2 in the window 130, or otherwise click next in the assistance window 150. Referring to FIG. 2, the second step of the calibration process includes selecting the associated measurement analyzing device, such as an associated vector network analyzer, TDR, etc. The assistance window 250 indicates to the user of the need to press the system button 120. It is noted that the assistance window 250 does not actually perform the selection of the system button 120 but rather indicates to the user of the need to perform this operation. Upon selection of the system button 120, a measurement system settings window 200 is provided, as illustrated in FIG. 3. The VNA that is detected by the system may be indicated in a window 202. The assistance window 260 indicates the possibility of selecting the VNA to be used for the measurement and calibration. The assistance window 260 also includes the location of where the section of the VNA is performed in the measurement system settings window 200. The VNA may also be selected from a user definable or preset list 204 (e.g., pull-down list). In this example, the selected VNA is identified as a Cascade Microtech ‘virtual VNA’ which is a simulated VNA. A virtual network analyzer is suitable when an actual network analyzer is not currently available or otherwise being used by others. The settings window 202 also indicates the model of the VNA as WinCalVirtual in the case of a virtual VNA; the serial number as SN 1001; the version number 4.0.0.159, and the options on the VNA as none. This information permits the user to readily determine if the selected network analyzer is the desired device together with validating version and configuration information of the device. In some cases, the version of the device may be out of date or otherwise inapplicable for the particular testing to be performed, and having this information presented along with the network analyzer selection is suitable to reduce the likelihood of having an unsuitable hardware configuration. Also, the versioning information is useful in the event updates are desirable. The selected VNA 204 is shown in the settings window 202.

A confirm communication button 206 is available to determine whether there is proper communication between the software and the selected network device 204. This is particularly useful when the same network analyzer has more than one potential driver, the selection of which is dependant on the type of communication channel being used (e.g., firewire, USB, GPIB, or other communication protocols). Accordingly, this permits the selection of the appropriate network analyzer, the particular communication protocol currently being used for that network analyzer, and confirm that the selected network analyzer is being used together with the communication protocol being used for the device. In the event that a device different than the selected device is present or the selected device does not acknowledge communication (e.g., improper communication protocol being used or otherwise not interconnected properly), then the user may remedy the communication issue. It is preferable that the option to provide a confirmation of the communication is provided to the user before actually attempting to calibrate or obtain measurements, which in the event of improper communication or improper driver will likely fail. The user may likewise select the stimulus settings 210 for testing the associated network analyzer. The selected settings are normally confirmed by selecting apply.

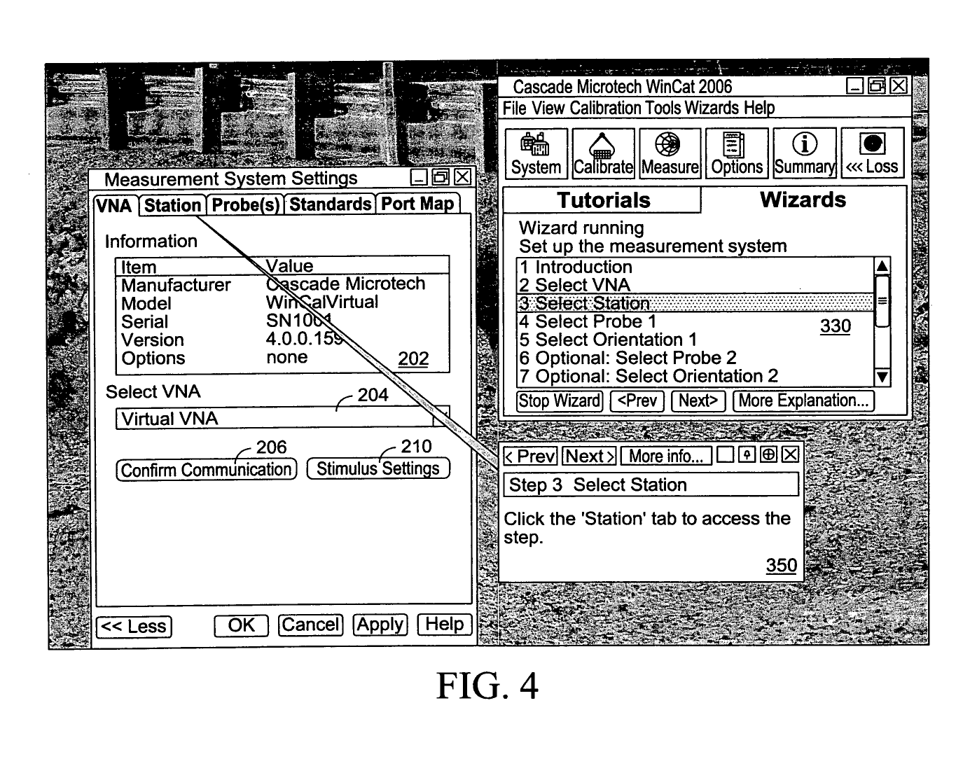

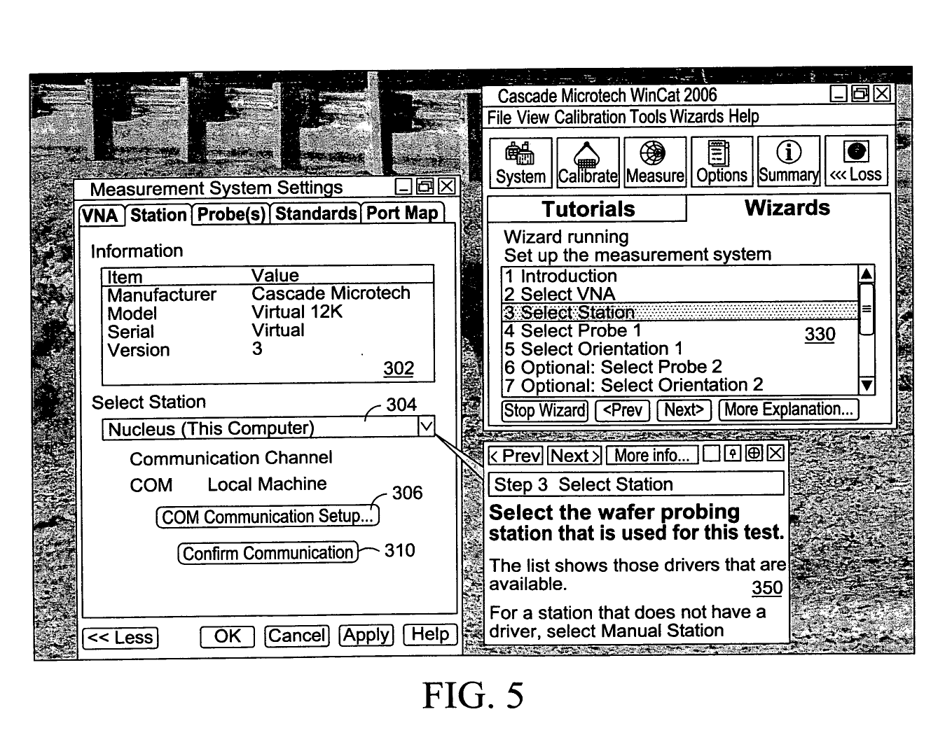

After selection of the settings for the VNA described with reference to FIG. 3, the user may click next on the assistance window 260, move to step 3 in the window 230, or otherwise select the station tab in the measurement system settings 200. The assistance window 350 illustrated in FIG. 4 indicates that step 3 in the calibration process is the selection of the “station” tab. The user selects the ‘station’ tab which changes the window to that illustrated in FIG. 5. The current station that is detected by the system may be indicated in the window 302. The station may also be selected from a user definable or preset list 304 (e.g., pull-down list). In this example, the selected probe station is identified as a Cascade Microtech which is a simulated. A virtual probe station is suitable when an actual probe station is not currently available or otherwise being used by others. The settings window 302 also indicates the model as a virtual 12K in the case of a virtual probe station; the serial number is virtual; and the version number is 3. This permits the user to readily determine if the selected probe station is the desired device together with validating version information. The settings window 304 also may indicate the list of available software drivers for the same probe station. In this manner, the user can select from a variety of different software drivers for the same probe station, since some drivers have features or capabilities that may be different from other drivers. A confirm communication button 310 is available to determine whether there is proper communication between the software and the selected probe station 304. A communication setup 306 be used to change the communication protocol. This is particularly useful when the probe station has more than one driver depending on the type of communication used or otherwise which software is preferable. Accordingly, the device with the desired communication being used or software selection may be selected. In the event that there is not proper communication, then the user may fix the communication issue. It is preferable that the option to provide a confirmation of the communication is provided to the user before actually attempting to take measurements, which in the event of improper communication or improper driver will likely fail. After selecting the probe station, selecting the appropriate communication software, and confirming the communication is established, the user may select apply.

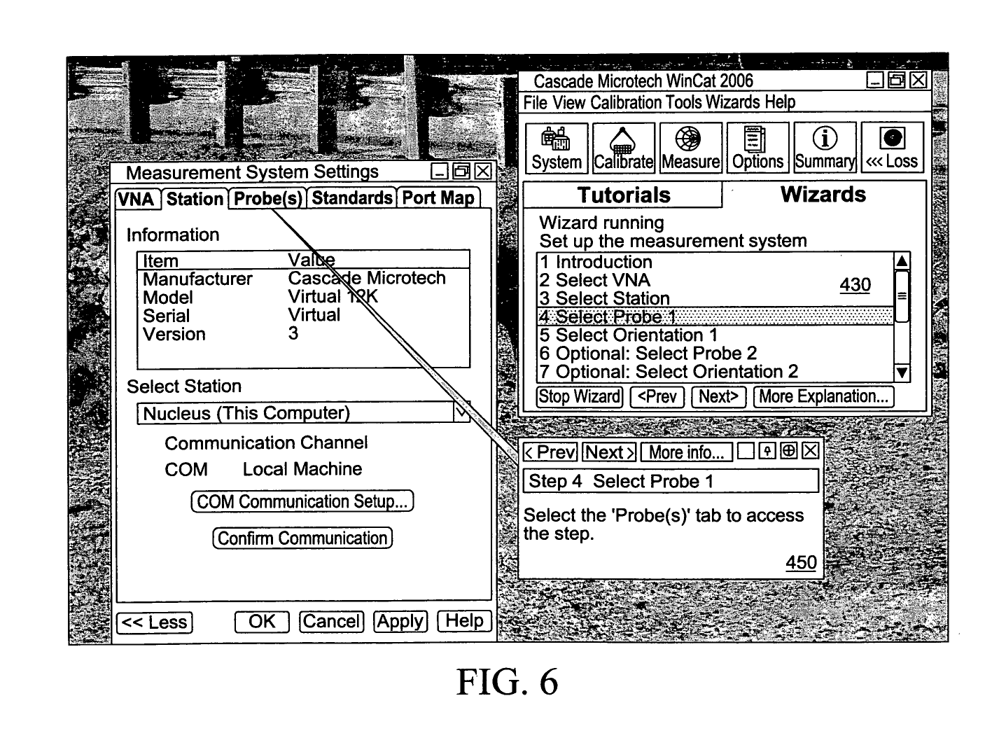

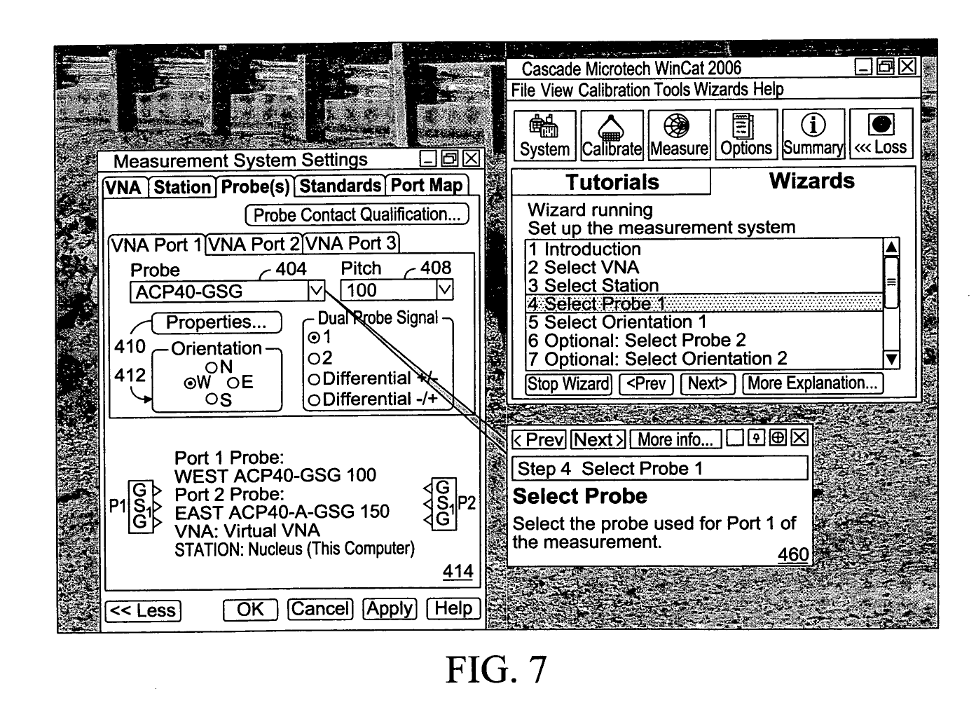

After selection of the station settings described with reference to FIG. 5, the user may click next on the assistance window 450, move to step 4 in the window 430, or otherwise select the probe (5) in the measurement system settings 200 as illustrated in FIG. 6. Referring to FIG. 7, the system then indicates at step 4 in the process within the assistance window 460 to select the probe to be used for port 1. The user then selects a probe from a list of possible probes from the selection window 404 that matches the probe attached to port 1 of the vector network analyzer. The selected probe may have one of several different configurations, such as for example, a signal probe, a ground-signal probe, a ground-signal-ground probe, a ground-signal-ground-signal-ground probe, or a differential probe. After selecting the particular probe within the selection window 404 for port 1, the system may automatically associated the appropriate measurement characteristics with the particular probe. In many cases, the measurement characteristics of the particular probe are provided by the manufacturer which are automatically or manually selected by the properties button 410. In other cases, the user may define the measurement characteristics of the probe by the properties button 410. The user may also select the pitch between the probing contacts of the selected probe with the pitch selection window 408. It also to be understood, that the user may configure the probe station with multiple ports, such as 2, 3, 4, 5, 6, etc. and the same number of ports is reflected on the probe calibration interface. In this manner, the number of probes is consistent between the setup and the probe (e.g., port) selection.

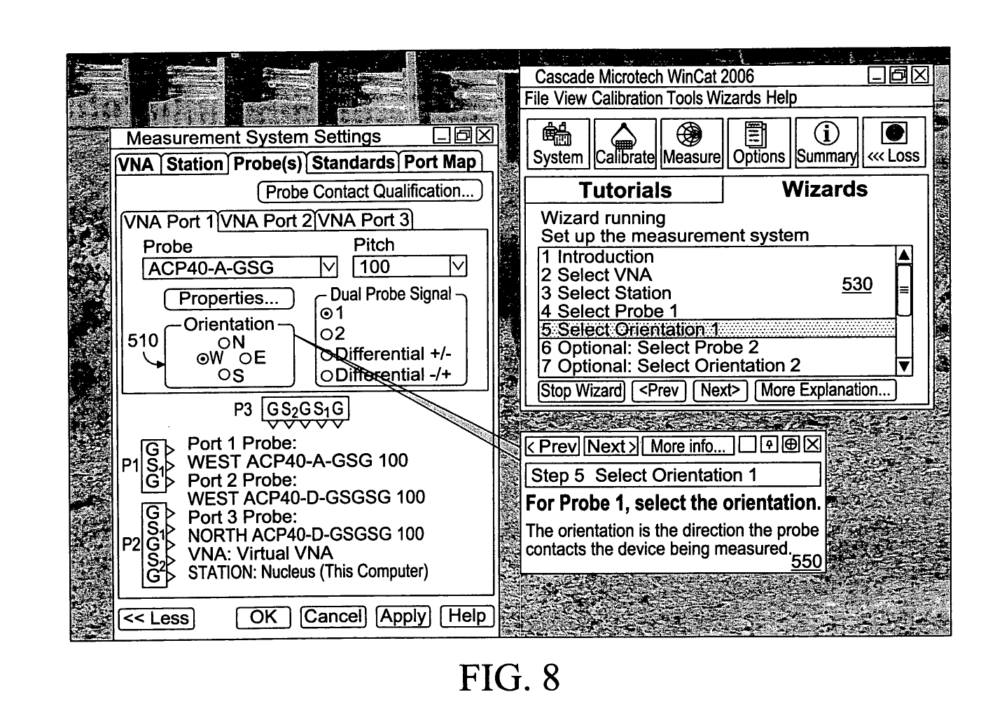

Historically, the calibration substrates used in the calibration process are structured such that the probes are assumed to be in an opposing east-west relationship to one another. Correspondingly, the previously existing calibration software likewise presumed this probing alignment and included no notion of probe orientation. It was observed that in some cases the actual probing configuration is different than merely east-west, and that this possibility should be accounted for in the calibration system. The different orientations may affect which substrates are suitable and the desirable structures for the calibration. For example, the probing configuration may be east-west, north-west, north-east, north-south, west-south, east-south, north-north, south-south, west-west, east-east, or otherwise. Further combinations may likewise be used for systems using more than 2 ports. Referring to FIG. 8, after selecting the desired probe, the assistance window 550, the user may select the orientation 510 of the probe associated with port 1, as being N (north), S (south), E (east) or W (west). The selection may be applied.

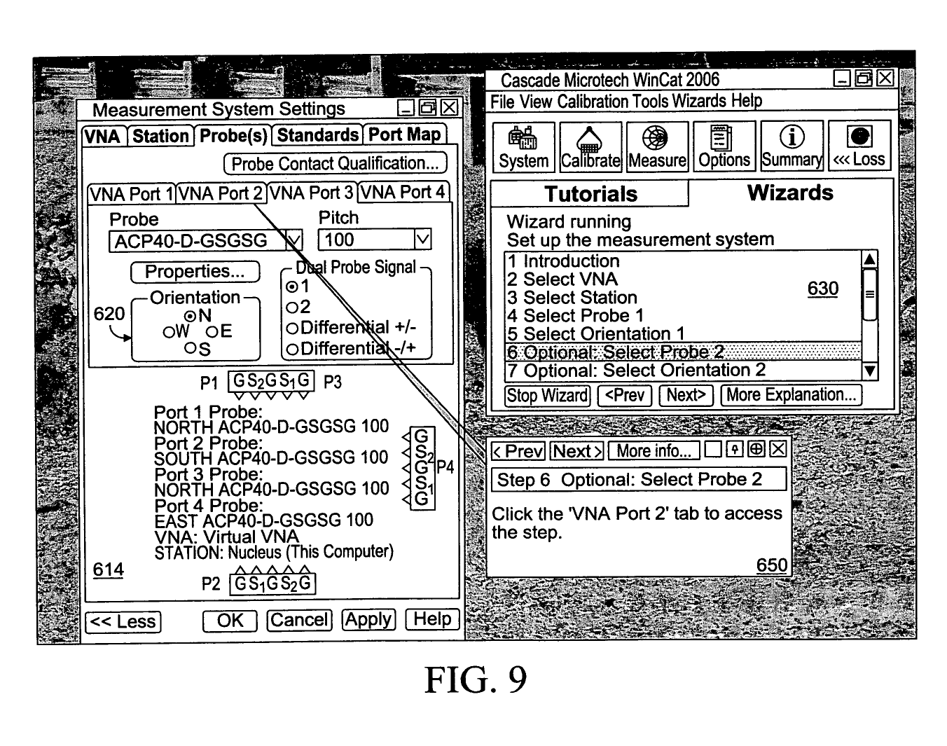

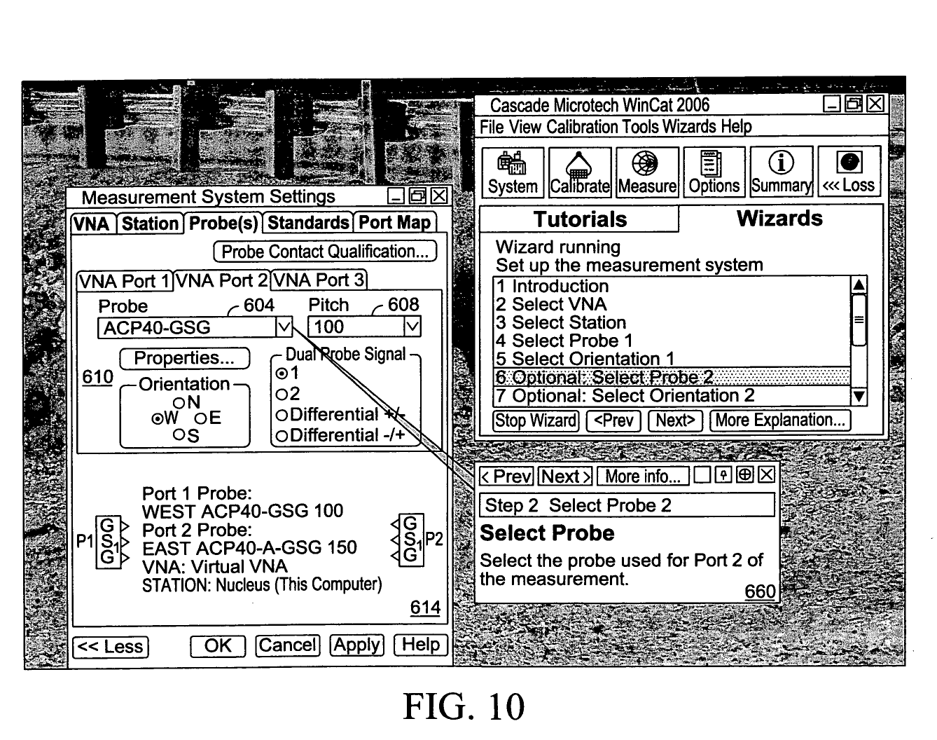

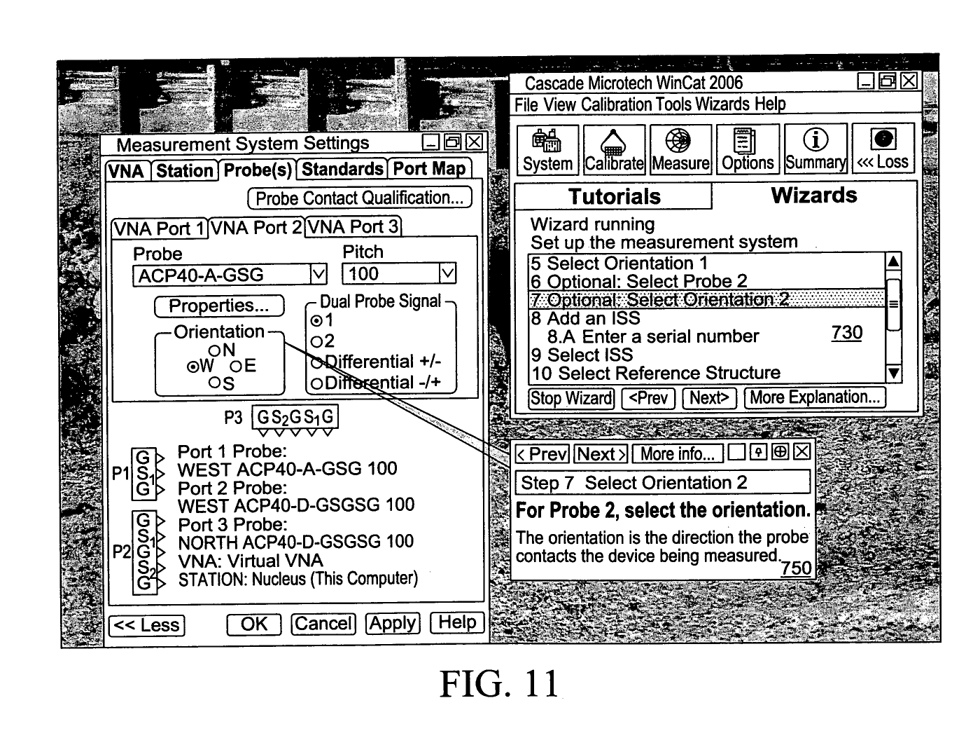

After selection of the probe and orientation for the first probe described with reference to FIG. 8, the user may click next on the assistance window 650, move to step 6 in the window 630, or otherwise select the probe for port 2 in the measurement system settings 200 as illustrated in FIG. 9. Referring to FIG. 10, the system then indicates at step 6 in the process within the assistance window 660 to select the probe to be used for port 2. The user then selects a probe from a list of possible probes from the selection window 604 that matches the probe attached to port 2 of the vector network analyzer. The selected probe may have one of several different configurations, such as for example, a signal probe, a ground-signal probe, a ground-signal-ground probe, a ground-signal-ground-signal-ground probe, or a differential probe. After selecting the particular probe within the selection window 604 the system may automatically associated the appropriate measurement characteristics with the particular probe. In many cases, the measurement characteristics of the particular probe are provided by the manufacturer which are automatically or manually selected by the properties button 610. In other cases, the user may define the measurement characteristics of the probe by the properties button 610. The user may also select the pitch between the probing contacts of the selected probe with the pitch selection window 608. The orientation of the probe on port 2 may be selected in a manner similar to port 1, as illustrated by FIG. 11. A similar process may be repeated for additional probes and/or ports, which may be in excess of four depending upon the system configuration.

Referring again to FIG. 9, a lower region 614 of the window illustrates the selected configuration for the ports. The illustration for each port includes, the probe's configuration, the probe's orientation, pitch, and the probe's type. The probe on port 1 is illustrated as a G-S-G-S-G (ground-signal-ground-signal-ground) type probe with a north orientation. In addition, textual information is included indicating “Port 1 Probe: NORTH ACP40-D-GSGSG 100”. For the dual signal probe, the probe selections 620 may be selected to indicate that signal path two is associated with port 1. The probe on port 2 is illustrated as a G-S-G-S-G (ground-signal-ground-signal-ground) type probe with a south orientation. In addition, textual information is included indicating “Port 2 Probe: SOUTH-ACP40-D-GSGSG 100”. For the dual signal probe, the probe selections 620 may be selected to indicate signal path one is associated with port 2. The probe on port 3 is illustrated as a G-S-G-S-G (ground-signal-ground-signal-ground) type probe with a north orientation. In addition, textual information is included indicating “Port 3 Probe: NORTH ACP40-D-GSGSG 100”. For the dual signal probe, the probe selections 620 may be selected to indicate that signal path one is associated with port 3. The probe on port 4 is illustrated as a G-S-G-S-G (ground-signal-ground-signal-ground) type probe with an east orientation. In addition, textual information is included indicating “Port 4 Probe: EAST ACP40-D-GSGSG 100”. For the dual signal probe, the probe selections 620 may be selected to indicate that signal path two is associated with port 4. It may be observed that to further assist the user in the configuration of the software to conform to the actual probing conditions, the probes are illustrated as graphical icons in the lower region 614 with their orientation. In addition, the graphical illustration of each probe provides an indication of the number of signal paths and also provides an indicated of the number of ground paths.

In some cases, it is desirable that the same physical probe be used for multiple ports, such as the north probe being used for both port one on signal path 2 and port three being used on signal path 1. In the case of the same physical probe being used for multiple ports, the system may represent that probe with a single probe. The representation may also include an indication as to which port is associated with which signal path. Also, the window 620 permits a pair of ports to be configured as a differential pair, e.g., +/− or −/+. A large set of ports may be configured in a similar manner. The user may apply the settings. In some cases, it is desirable to include a selection box that permits the illustration of multiple ports on the same probe, or otherwise showing the multiple ports with multiple probes. In this manner, the user has additional control over the interface.

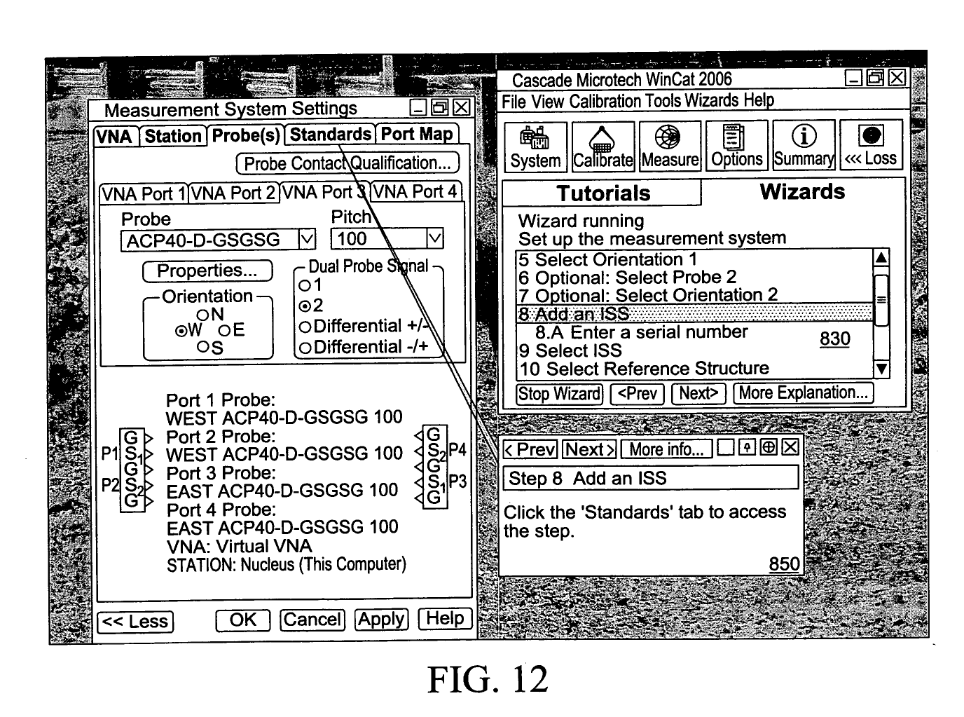

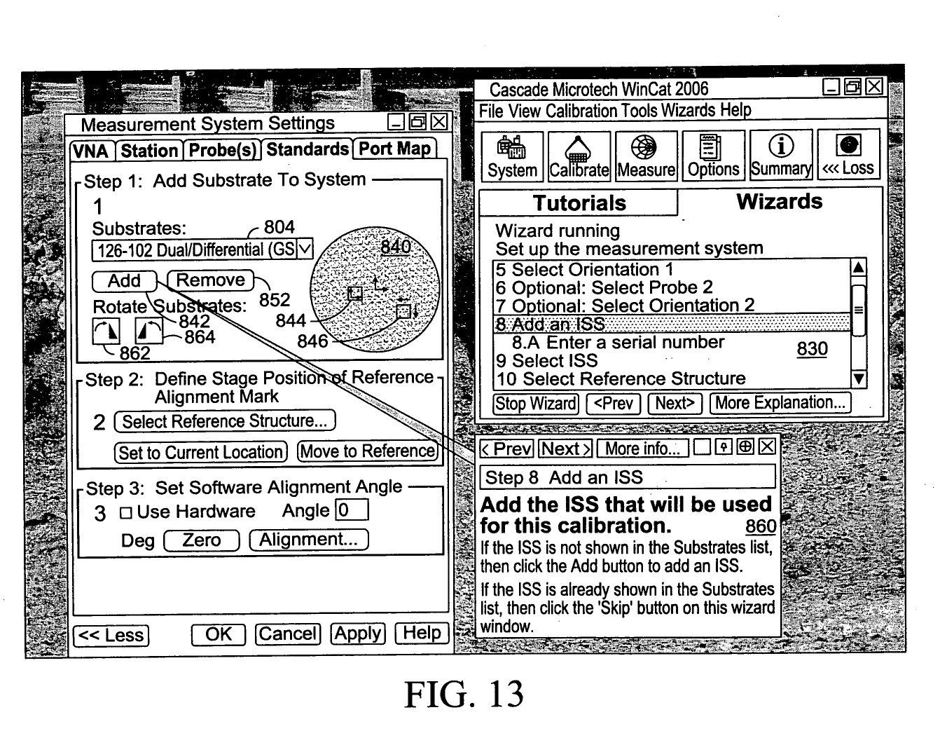

After selection of the probes and their orientations, the user may click next on the assistance window 850, move to step 8 in the window 730, or otherwise select the standard in the measurement system settings 200 as illustrated in FIG. 12. Referring to FIG. 13, the system then indicates at step 8 in the assistance window 860 to add an ISS calibration substrate. The ISS standard includes a set of structures thereon which are used for calibration of the probes. In many cases, the calibration structures include open circuit, short circuits, loads, through, and crosses. In most cases, the loads are 50 ohms or another known value. In most cases, the loads have a value within a certain tolerance, such as +/−0.1%.

The user selects a calibration substrate from a list of possible substrates from the selection window 804 that matches the calibration substrate being used. The user may select from many different possible calibration substrates. A simulated region 840 illustrates a support onto which the calibration substrate may be located. By indicating the add button 842 a substrate is positioned on the region 840. The substrate 844 may be moved by the user. In many cases, there are calibration structures on one substrate that are different from calibration structures on other substrates. In the case that multiple calibration structures are desired for a particular type of calibration, then either a single calibration substrate needs to be acquired that has those structures, or multiple calibration structures needs to be obtained that collectively include those calibration structures.

To facilitate more flexible calibration needs, the user may add multiple substrates to the region 840, of the same or different types. In this manner, the user may select from among many different or the same substrates as desired in order to perform the desired calibration of the system. Substrates may be removed with the remove button 852. In many cases, the calibration structures on a particular substrate may not always be in a horizontal orientation, but rather in a vertical orientation and/or horizontal orientation (or other orientation(s)). A rotation selection 862 (clockwise) or rotation selection 864 (counter-clockwise) may be selected to rotate the substrate 90 degrees (or otherwise) in the selected direction. In this manner, each substrate can be aligned for the particular tests to be performed based upon the orientation of the probes and/or the orientation of the calibration structures to be used on the substrates. When using multiple calibration substrates it is particularly useful to be able to orient them in different orientations. The relative graphical location is also typically representative of the location of the substrates on the chuck, such as a calibration chuck. In this manner, the operator can have both a representative view on the display that generally matches the position of the substrates on the chuck. In some cases, the probe station will include a primary chuck upon which the wafer is situated and an auxiliary chuck that is spaced apart from the primary chuck upon which the substrate is located. In this case, the interface may determine that the particular probe station selection includes such an auxiliary chuck and automatically provide an illustration that includes a primary chuck and an auxiliary chuck upon which the substrates are situated. In other cases, the selection of a primary and auxiliary chuck may be user selected.

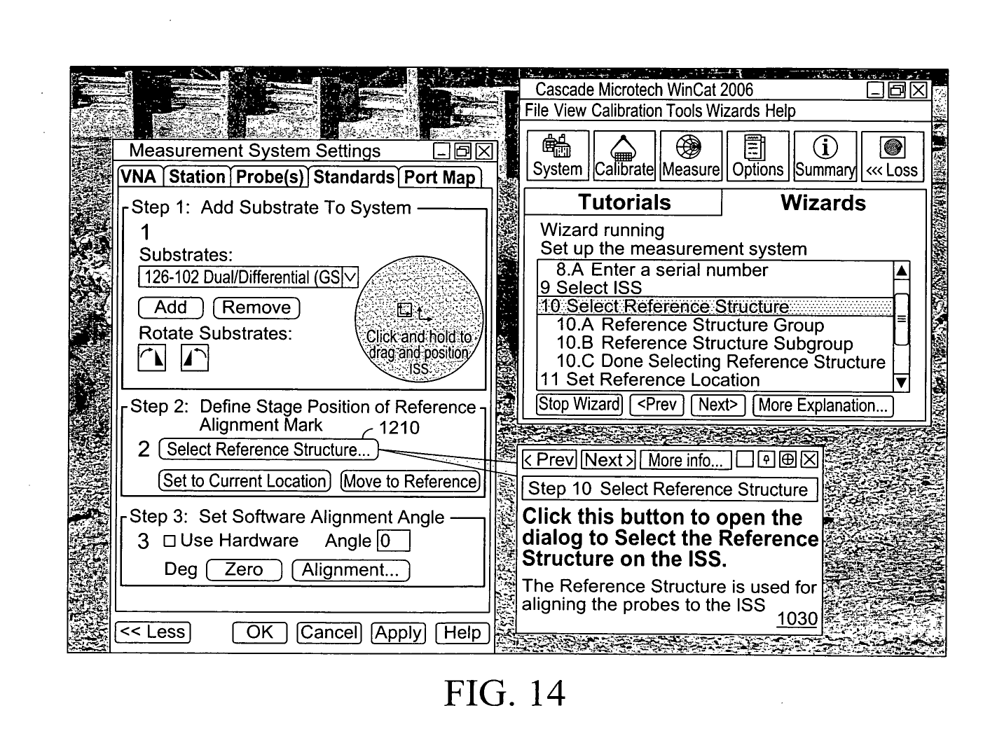

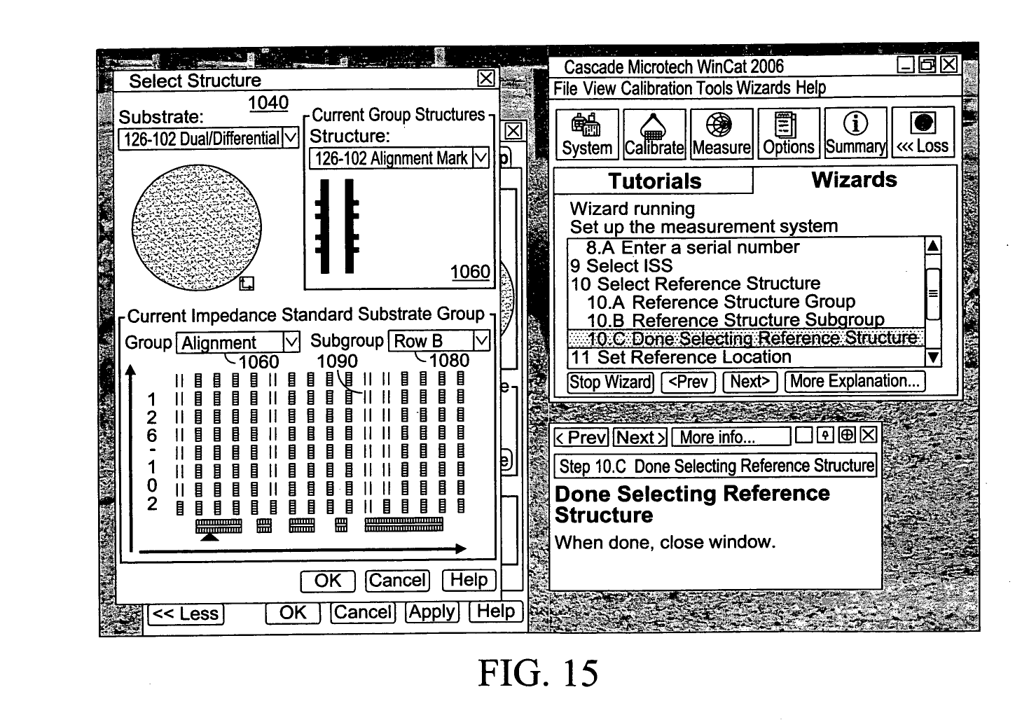

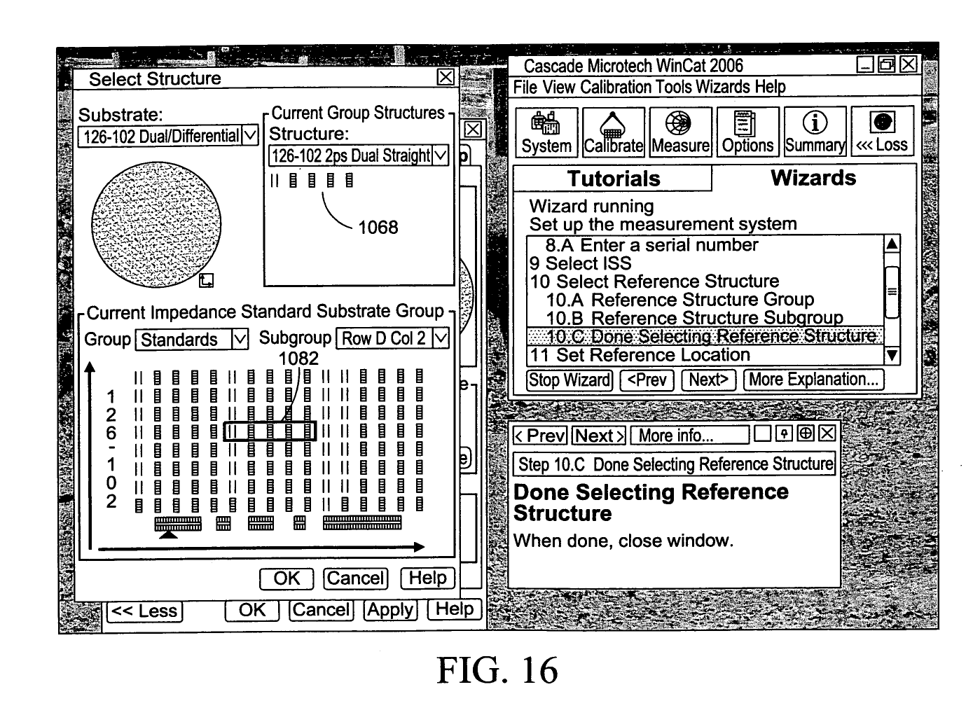

After selection of the probes and their orientations, the user may click next on the assistance window 860, move to step 10 in the window 830, or otherwise select the standard in the measurement system settings 200 as illustrated in FIG. 13. Referring to FIG. 14, the system then indicates at step 10 in the assistance window 1030 that the user should select the reference structure(s) 1210 on the actual substrate to be used. Referring to FIG. 15, upon selection of the reference structure 1020 a window 1040 is provided where the user may select a reference structure group 1060, such as an alignment mark. In addition, the user may select which subgroup 1080 of the alignment structure. For example, the user may select an alignment mark 1090 in row B (second row). This indicates where the probe is aligned to, which is performed by the user with a microscope or otherwise by automatic alignment mechanisms. Referring to FIG. 16, the group may be a standard which refers to those structures used for a particular standard. The standard grouped in FIG. 16 is a group of 5 structures 1082 at Row D, Column 2 that includes a short, open load, through, and straight. In addition, a plurality of different non-adjacent structures may be selected on the substrate to achieve the desired test. This is particularly useful when portions of a particular calibration group on the calibration substrate wears out after repeated use. Thus the other structures within the group may continue to be used. Illustrations 1068 illustrate the type of reference structure that is selected. It is understood that the user may align the probes to any structure or portion of the substrate and based upon this structure, the system may automatically move to other structures on the substrate. The system also includes a ‘map’ of the location of the calibration structures on the substrate, so that the system can move from structure to structure, even if the structures are not aligned but rather scattered across the substrate. Hence, the alignment need not be to a particular row or device of the substrate.

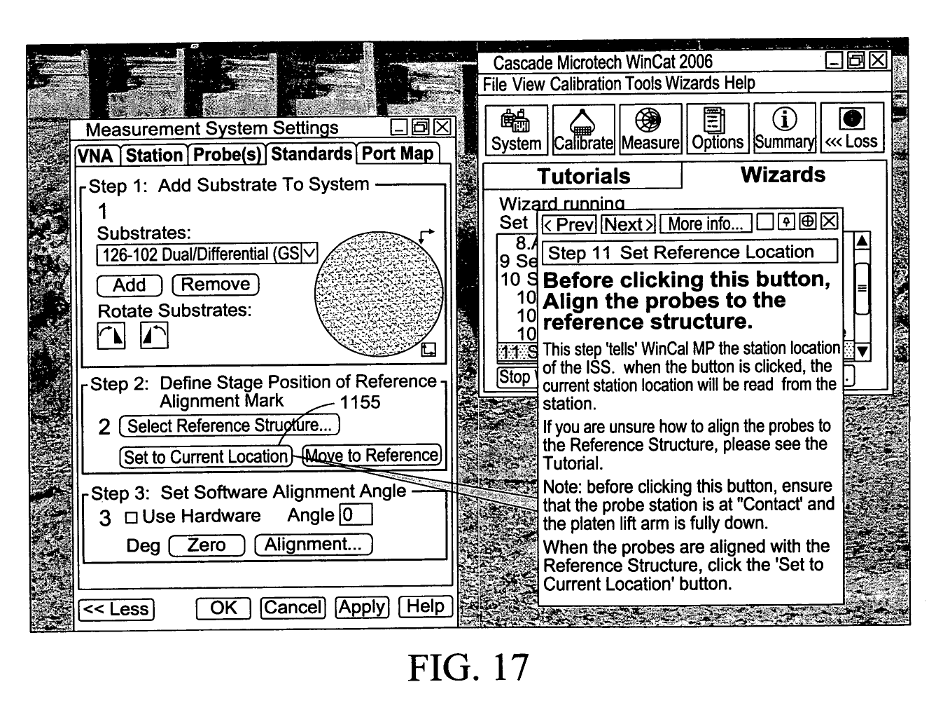

After selecting the desired structure on the substrate upon which to perform the calibration test at step 11, it desirable to select an appropriate reference location as illustrated in FIG. 17. The user should position the probes on the desired location of the substrate, such as on an alignment mark or other calibration structure. Then the user should set the probe to current location with button 1155. In this manner, the system has now associated the desired substrate and a location on the desired substrate with the actual probing system.

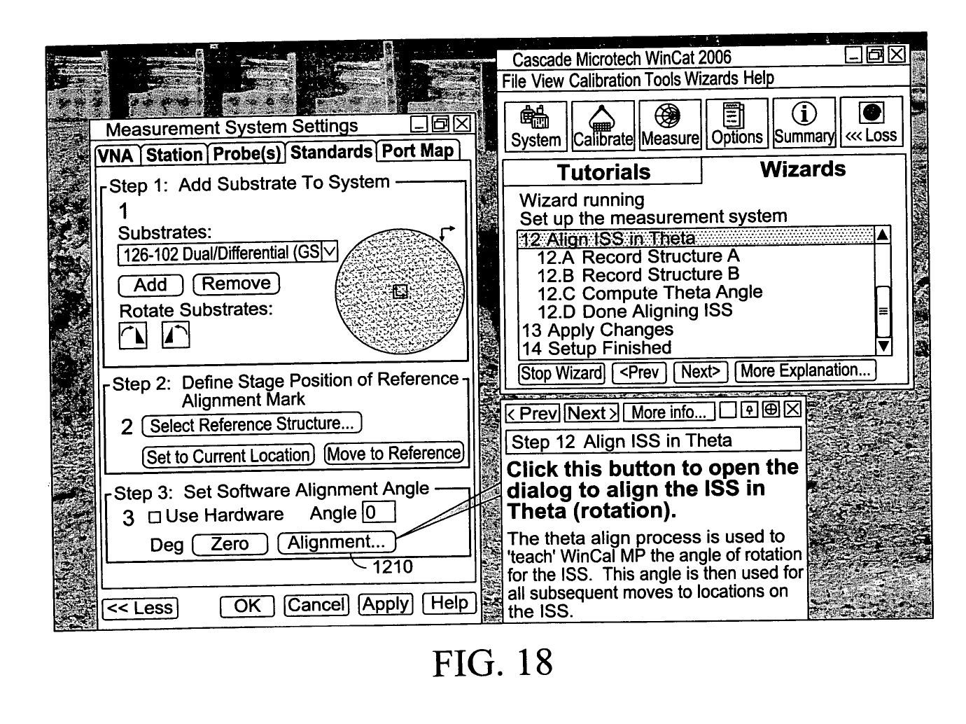

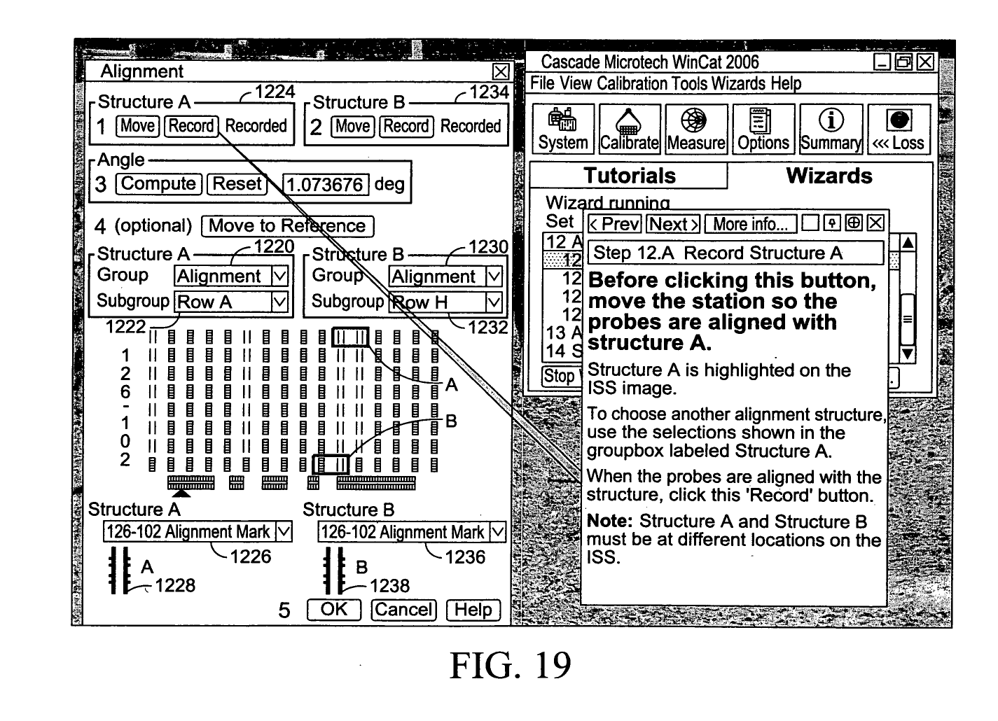

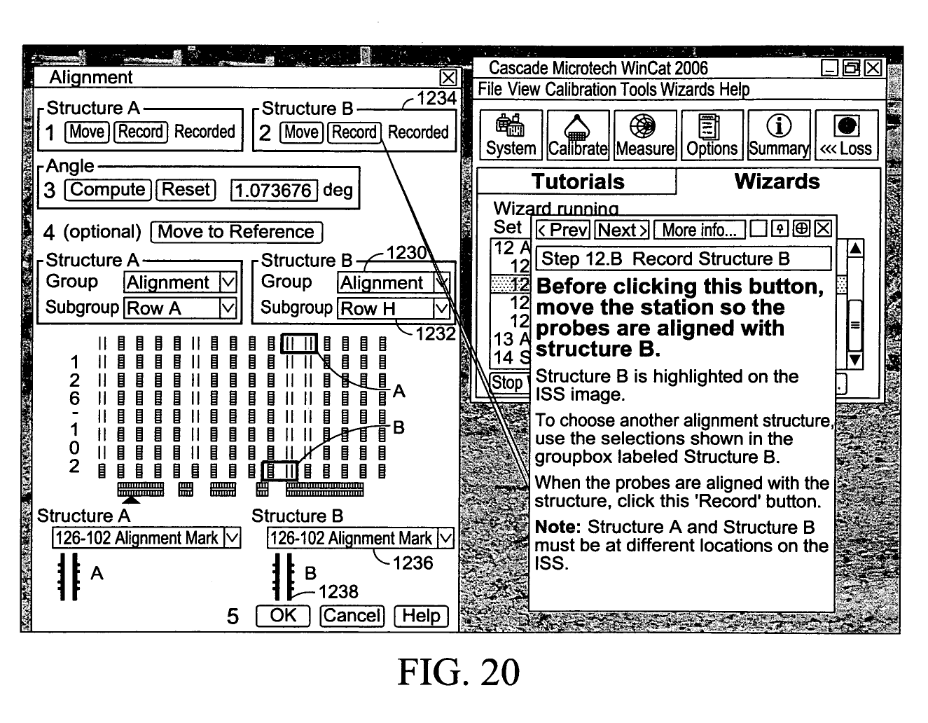

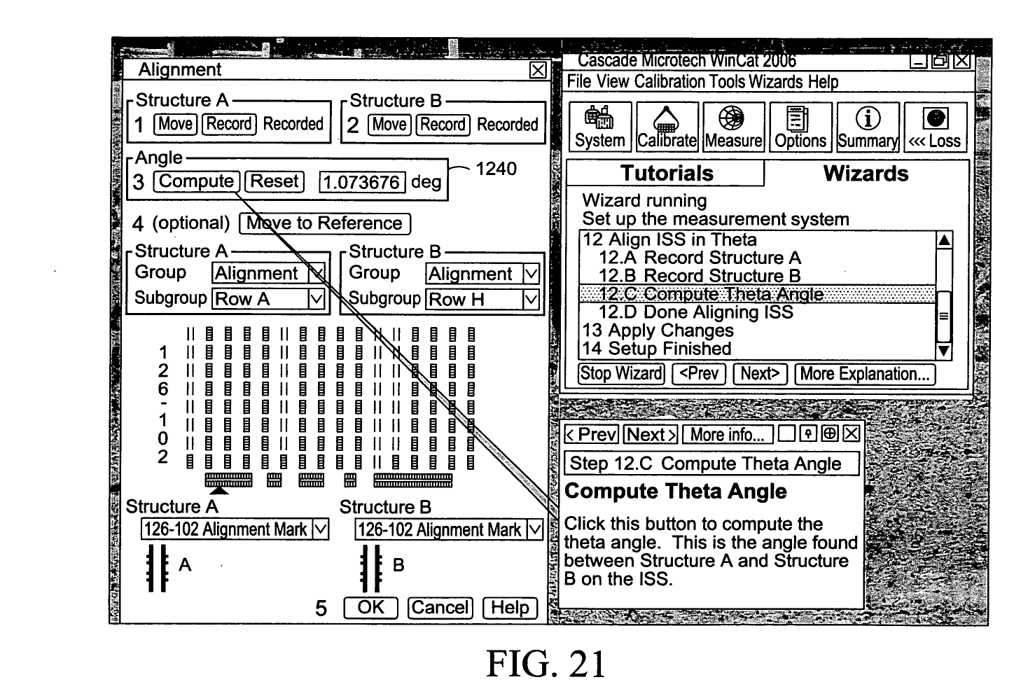

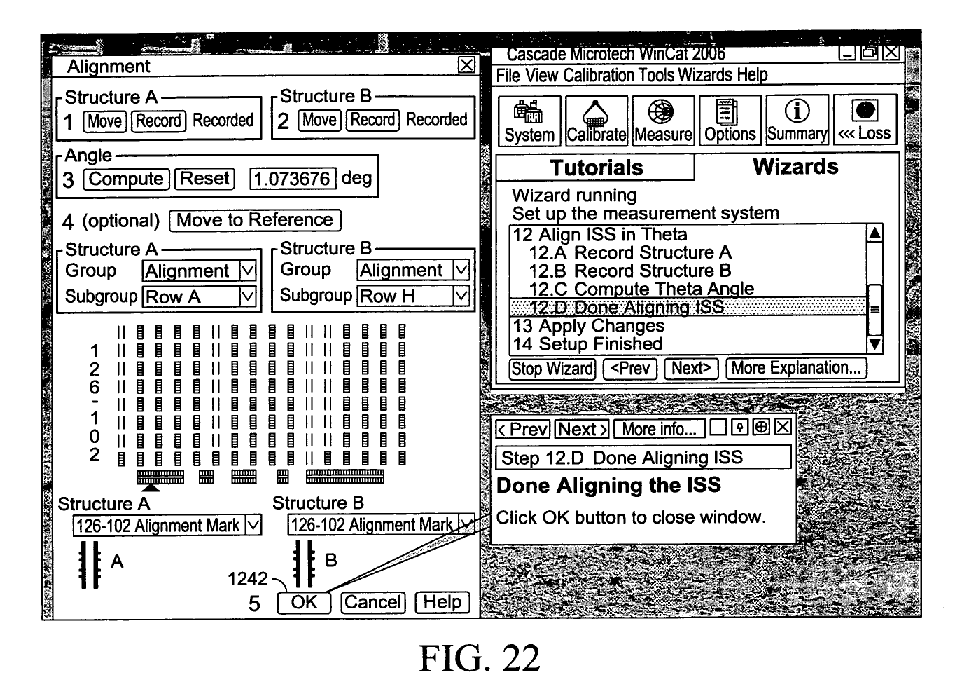

Referring to FIG. 18, the user then uses the alignment mechanism to adjust the theta alignment of the substrate with respect to the x-y-z movement of the stage and/or x-y-z movement of the probes. The user selects the alignment mechanism 1210 which opens an alignment mechanism illustrated in FIG. 19. The user then may select a first group 1220, and a subgroup 1222 which is identified as group “A”. The user then may align the probe to this reference structure using the move function then click record 1224 to identify the location. Referring also to FIG. 20, the user then selects a second group 1230, and a subgroup 1232 which is identified as group “B”. The user may align the probe to this reference structure using the move button then click record 1234 to identify the location. The type of structure A is identified at 1226 together with a graphical illustration of that structure 1228. The type of structure B is identified at 1236 together with a graphical illustration of that structure 1238. Referring to FIG. 21, the user may then compute the theta angle between reference structure A and reference structure B on the substrate by clicking button 1240. In this manner, the user may get the orientation and spacing for proper future positioning of the probes on the calibration substrate. The system may use the alignment structure as the base reference, if desired. Referring to FIG. 22, when completed the user may select the “OK” button 1242 to accept and close the window. In this manner, the user is not required to provide accurate orthogonal alignment of the substrate with respect to the stage movement.

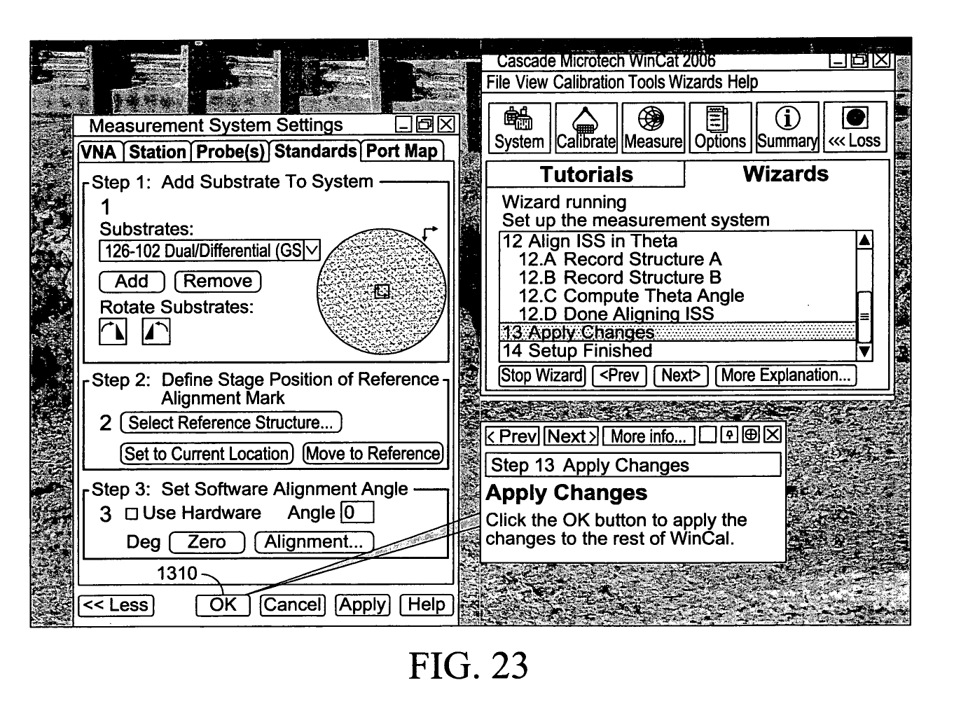

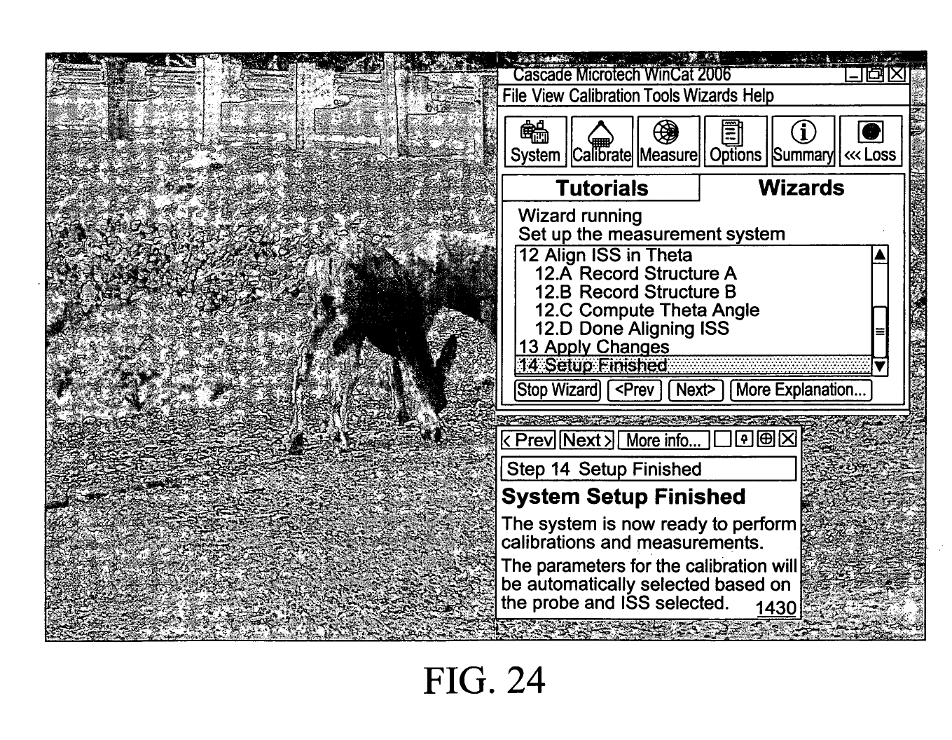

Referring to FIG. 23, when these selections are made, the user may apply the changes using the “OK” button 1310. Referring to FIG. 24 the user may has completed the setup and it notified of this event in the assistance window 1430.

The system may likewise include a wizard editor for the calibration system.

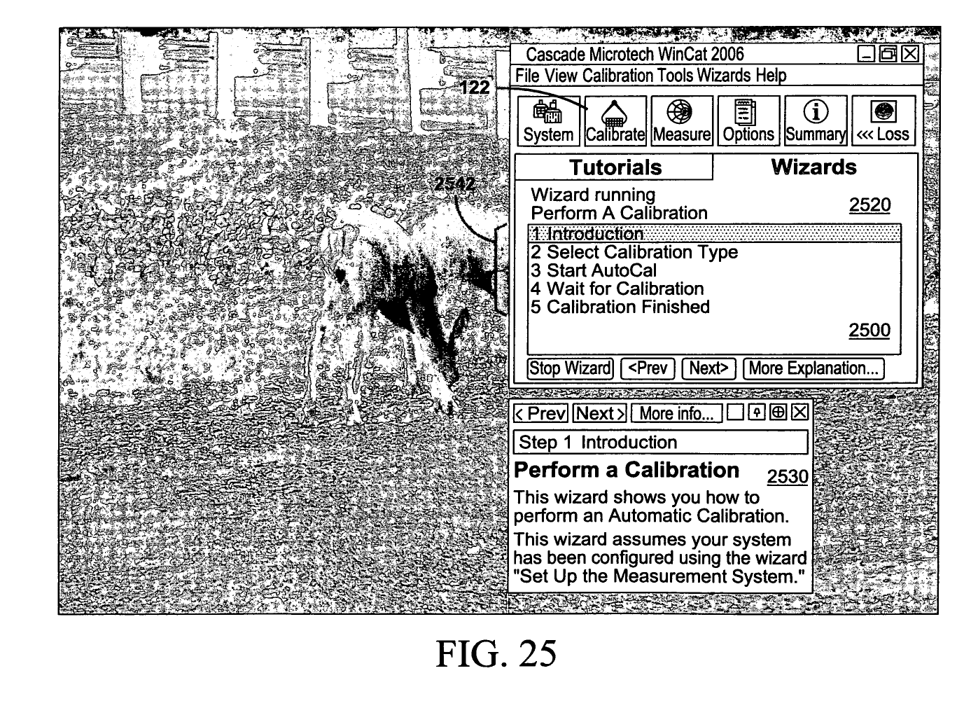

Referring to FIG. 25, the system may include a wizard to perform the actual calibration includes a first window 2500 which displays a selection of the principal tasks for performing a calibration. A window 2520 indicates that the wizard is being used and the steps 2542 that the user is guided through by the wizard. The wizard provides an assistance window 2530 that includes further information regarding the particular step that is being performed by the user. The description in the assistance window 2530 corresponds to the particular item being highlighted by the wizard.

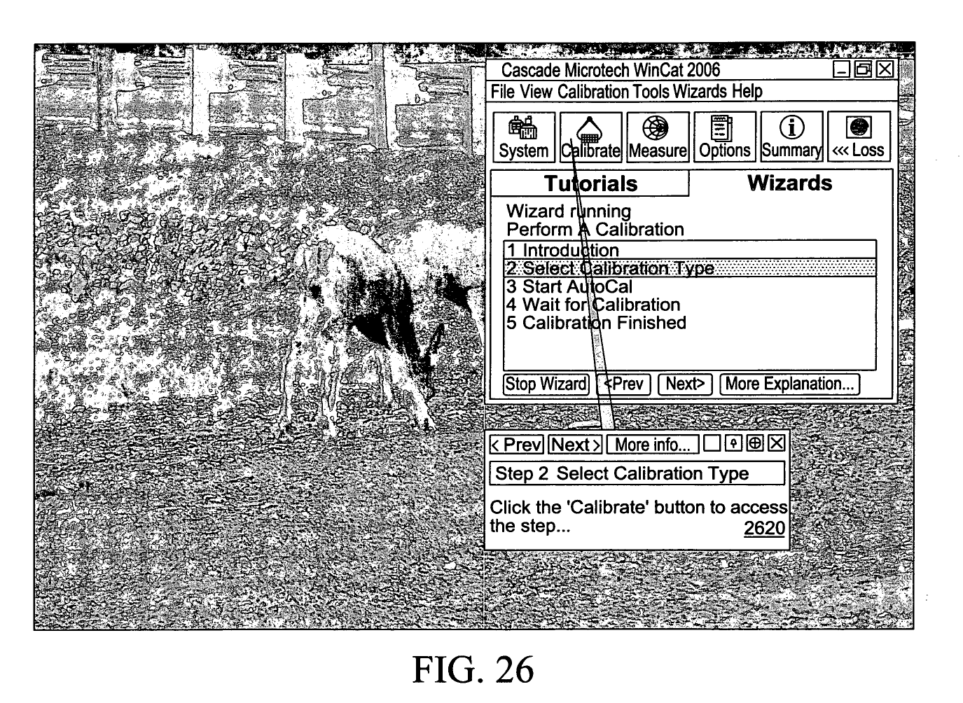

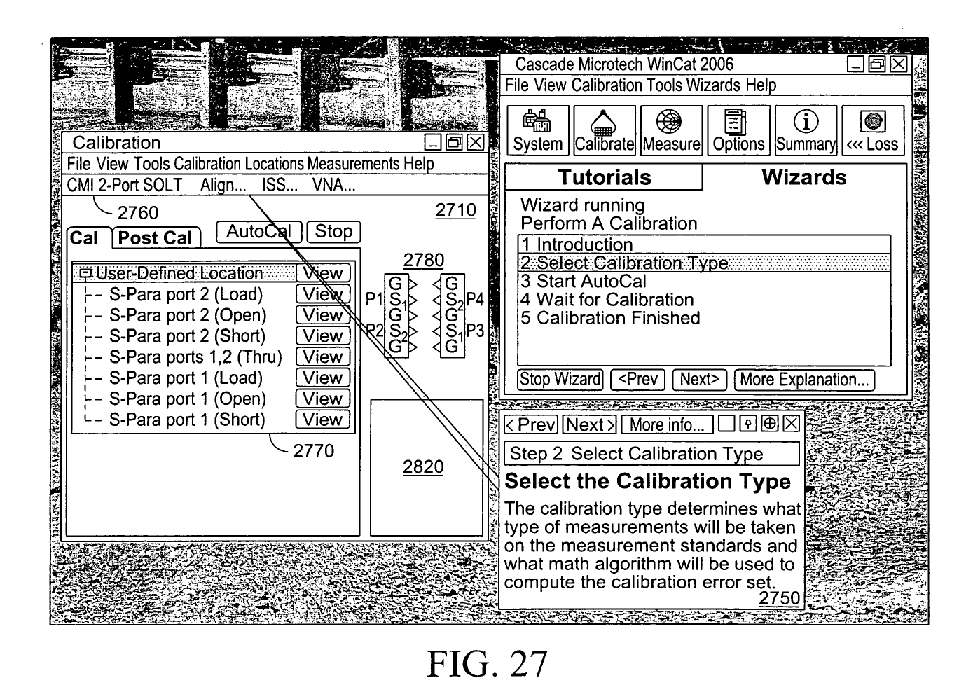

The assistance window 2530 preferably includes textual information that further guides the user through the calibration process. To calibrate, as indicated by the assistance window 2530, the user may select the ‘calibrate’ button 122, move to step 2 in the window 2500, or otherwise click next in the assistance window 2530. Referring to FIG. 26, the second step of the calibration process includes selecting the calibration type as illustrated in the assistance window 2620. Referring to FIG. 27, upon selection of the calibration type a window 2710 opens. An assistance window 2750 indicates that the calibration type 2760 determines what type of measurements will be taken on the measurement standards and what technique will be used to compute the calibration error set. The user may select from among several different types of measurements.

The window 2770 shows a ‘plan’ for performing a 2-Port SOLT test. For example, the test may include testing port 2 for load, port 2 for open, port 2 for short, ports 1 and 2 for through, port 1 for load, port 1 for open, and port 1 for short. By illustrating a test-by-test plan for performing the selected calibration the user may step through the calibration process if performed manually. In this manner, the user will perform the calibration tests in the proper order in order to determine the calibration coefficients.

In some cases, the “autocal” button 2780 may be selected. The system then may automatically reposition the probes on the appropriate structures on the calibration substrate in an appropriate order to perform the test. The tests may be performed on a continuous set of calibration structures if desired. Also, the tests may be performed on a non-continuous set of calibration structures if desired. The system may permit the user to identify those structures that are not suitable for testing or otherwise worn from use, and thus not use those calibration structures.

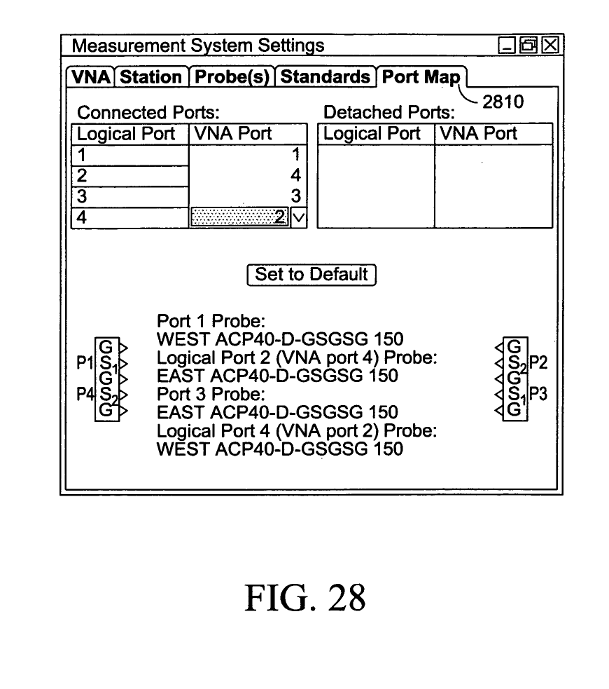

The window region 2780 illustrates the logical layout of the probing configuration which is straightforward to follow. The logical layout is typically an indication of which port is connected to which probe. Referring to FIG. 28, a port map 2810 indicates a mapping between the logical ports connected to the probe(s) and the actual physical port of the VNA. In this manner there is a mapping between the probes and the physical connection at the VNA.

In some cases the actual physical layout of the probes is different than that illustrated in the graphic region. In this case, the actual test to be performed to achieve the necessary calibration may vary from what would otherwise appear to be the test. To assist the user, if manually selected calibrations, the window 2820 may display a representative graphic of the calibration structure to be used. For example, the graphic may be a look-back, through, diagonal, short, open, etc.

The list of the tests may likewise be shown together with the appropriate structure to perform that test based upon the logical port and VNA port mapping. In addition, the appropriate test may be based upon the physical probes, the structures on the particular substrate, and/or the orientation of the substrate. When the tests are being performed, the graphical illustration may change to illustrate which structure is being used for the particular step of the test. In this manner, the user may track the testing progress.

When the calibration process is completed, the system preferably provides the calibration parameters to the VNA. In addition, the data may be viewed in a reporting system.

While the system, if properly operated, tends to provide accurate calibration parameters. There are other factors that may influence the ability to obtain quality calibration parameters. For example, the cabling between the vector network analyzer and the probes may be faulty or is not suitably connected at its terminals. In other cases, improper cabling may be used, which is difficult to determine as being improper unless the operator carefully checks the specifications of the cabling. In some cases, the probe itself will be faulty to a greater or lesser degree, in which case the calibration parameters will not be proper. During a calibration process the operator, or the system, needs to make proper contact with minimal contact resistance between the probes and the calibration structures on the substrate. A poor contact with excess contact resistance results in inaccurate calibration parameters. In some cases, the operator will position the probe tips slightly off the contact pads on the device under test, which tends to result in inaccurate calibration parameters. At times the actual vector network analyzer itself is faulty or the settings of the vector network analyzer are improper for calibration, once again resulting in inaccurate calibration parameters. In many cases, the particular calibration substrate includes loads for which a selected set are ‘trimmed’ to within a suitable tolerance level. The remaining loads are typically not ‘trimmed’ to within the tolerance levels, and hence remain untrimmed. The ‘trimming’ of the loads merely refers to modifying the value of the resistance of a load which may be performed in any manner, such as for example, physical trimming, heating, stretching, or otherwise.

After considering all of the potential pitfalls of obtaining an accurate calibration for subsequent probing it was determined that the setup of the calibration system provides sufficient data from which to generally determine what the calibration parameters should be. The system includes a description of the calibration substrate being used, and the characteristics of the calibration structures. In many cases the characteristics are either ‘fully know’ or ‘partially known’. In this manner, the system is generally aware of what the characteristics of the calibration substrate structures should be.

The system may also know the general characteristics of the cables, which tend to be stable over reasonable periods of time. Also, the system may also know the general characteristics of the vector network analyzer which also tends to be stable over reasonable periods of time. Moreover, the system may be aware of the characteristics of the vector network analyzer with particular settings being selected, such as for example, the attenuation, the frequency range, and the power levels. In addition, the probes are also “known” with parameters being provided by the manufacturer or provided by the operator to the system. In many cases, these ‘known’ characteristics are the result of default values, values provided by the system, values calculated by the system, or otherwise inferred or measured from previous calibrations of the system (same or different configuration).

Based upon the estimated characteristics of the system, such as being a function of the calibration substrate, the cables, the vector network analyzer, the settings of the vector network analyzer, and/or the probe, the system may calculate an estimation of the system error terms. The estimated system error terms, while in many cases not precisely accurate, will tend to provide an indication of the anticipated error terms as a result of calibration.

To simply the determination of these parameters, the operator may perform a reference coaxial calibration. This calibration tends to take into account the vector network analyzer together with the cables. Based upon this reference coaxial calibration or the parameters determined from such a reference coaxial calibration, the system may then incorporate an estimation of the probe characteristics (e.g., a delay or S-parameters). This combination may provide a set of estimated system error terms, while in many cases not precisely accurate, will tend to provide an indication of the anticipated error terms as a result of calibration.

Another technique is to obtain the an estimated system error terms and then obtain a set of actual measurements. Based upon the actual measurements an estimate of the characteristics of the calibration substrate may be determined. Then the calibration for the estimated substrate may be compared against the anticipated characteristics of the substrate. Based upon these comparisons, a determination may be made if the calibration is likely a good one.

The system may likewise monitor the calibration characteristics of the system over time during different calibrations. In this manner, the system keeps updating its measured calibration coefficients rather than having a merely static configuration. The updated characteristics are of assistance in attempting to determine whether the current calibration is a good calibration.

With the estimated system error terms and knowledge of the particular calibration substrate, such as its characteristics, the system can determine what calibration the calibration parameters should generally be or otherwise what the characteristics of the calibration parameters should appear like. This may be compared against the actual calibration parameters determined from the calibration. If the two calibration sets are sufficiently similar then the system may indicate that a good calibration was performed, if the two sets are insufficiently similar then the system may indicate that the calibration is suspect.

1. A method for calibrating a probe measurement system comprising an analyzing device, a probe station and a probe, said method comprising the steps of:
(a) displaying an identity of an analyzing device to a user of said probe measurement system;
(b) enabling said user to identify to said probe measurement system said analyzing device included in said probe measurement system;
(c) upon selection of an analyzing device, displaying an identity of a probe station;
(d) enabling said user to identify to said probe measurement system said probe station included in said probe measurement system;
(e) upon identification of a probe station, displaying an identity of a probe; and
(f) enabling said user to identify to said probe measurement system said probe included in said probe measurement system.
